(19) United States
(12) Patent Application Publication
(10) Pub. No.: US 2025/0204177 A1
(43) Pub. Date: Jun. 19, 2025

(54) DOUBLE-SIDED DISPLAY DEVICE AND DRIVING METHOD OF DOUBLE-SIDED DISPLAY DEVICE

(71) Applicant: HKC CORPORATION LIMITED, Shenzhen (CN)

(72) Inventors: ZHONGLIN CAO, Shenzhen (CN); Chuan Wu, Shenzhen (CN); Wenyu Yi, Shenzhen (CN); Yajuan Feng, Sehnzhen (CN); Dongmei Wei, Shenzhen (CN); Jie Chen, Shenzhen (CN); Haijiang Yuan, Shenzhen (CN)

(21) Appl. No.: 18/974,833

(22) Filed: Dec. 10, 2024

(30) Foreign Application Priority Data
Dec. 19, 2023 (CN) 202311751923.6

(51) Int. Cl. H10K 59/128; G02F 1/1333; G02F 1/1335; H10K 59/38; H10K 59/65; H10K 59/80

(52) U.S. Cl. CPC H10K 59/128; G02F 1/133342; G02F 1/13338; G02F 1/133504; G02F 1/133512; G02F 1/133514; G02F 1/133553; H10K 59/38; H10K 59/65; H10K 59/878; H10K 59/8792

(57) ABSTRACT

A double-sided display device and a driving method of the double-sided display device are disclosed. The double-sided display device includes a first display panel and a second display panel for displaying a front side image and a back side image of the double-sided display device respectively. A pixel overlap area is disposed between the first display panel and the second display panel. The pixel overlap area is divided into multiple opaque sections and transparent sections. The first display panel includes an organic light-emitting layer that emits light in the first direction and the second direction in opposite directions. The light in the first direction displays the front side image on a display surface of the first display panel. The light in the second direction passes through the transparent section of the pixel overlap area and displays the back side image on a display surface of the second display panel.

### CROSS-REFERENCE TO RELATED APPLICATIONS

This application claims the priority and benefit of Chinese patent application number 2023117519236, titled “Double-sided Display Device and Driving Method of Double-sided Display Device” and filed Dec. 19, 2023 with China National Intellectual Property Administration, the entire contents of which are incorporated herein by reference.

### TECHNICAL FIELD

This application relates to the field of display technology, and more particularly relates to a double-sided display device and a driving method of the double-sided display device.

### BACKGROUND

The description provided in this section is intended for the mere purpose of providing background information related to the present application but doesn't necessarily constitute prior art.

As people's requirements for display quality become higher and higher, LCD panel products cannot meet the requirements of lightness, thinness, fast response and low power consumption. OLED panel (Organic Light Emitting Diode) display technology has gradually become the mainstream display technology with its advantages of fast response speed, wide operating temperature range, high contrast, large viewing angle, ultra-thin panel, and its capabilities of flexible display and transparent display.

A double-sided display is a device that can display images on both sides of the display device. It has a wide range of applications in, such as business halls in window industries e.g. the communications industry, government windows, the financial industry, and the transportation industry; public places with large traffic such as airports, train stations, subway stations, and canteens; and electronic products such as digital cameras, video cameras, and mobile phones. Double-sided display devices may be two OLED display panels placed opposite to each other. In order to save energy, one of the OLED panels is replaced with an LCD panel. In order to reduce thickness, the backlight module of the LCD panel is directly removed, thereby realizing a shared backlight. However, during display, the display effect of the display surface of the LCD panel may be very poor due to the brightness of the OLED light source, thereby affecting the quality of the double-sided display of the double-sided display device.

### SUMMARY

It is therefore one purpose of the present application to provide a double-sided display device and a driving method of the double-sided display device, so as to improve the quality of the double-sided display images of the double-sided display device.

The present application discloses a double-sided display device. The double-sided display device includes a first display panel and a second display panel. The first display panel displays a front side image of the double-sided display device. The second display panel displays a back side image of the double-sided display device. A pixel overlap area is disposed between the first display panel and the second display panel, and the pixel overlap area is divided into a plurality of opaque sections and a plurality of transparent sections. The first display panel includes an organic light-emitting layer, and the organic light-emitting layer emits light in a first direction and a second direction. The first direction and the second direction are opposite directions. The light in the first direction displays the front side image on the display surface of the first display panel. The light in the second direction passes through the transparent section of the pixel overlap area and displays the back side image on the display surface of the second display panel.

In some embodiments, a first reflection layer is disposed in the pixel overlap area. The first reflection layer is arranged in the opaque section. The first reflection layer is spaced apart from the second display panel. Along the first direction, the spacing between the first reflection layer and the second display panel is S1, wherein 0<S1≤3 mm.

In some embodiments, a first light mixing region is formed between the first reflection layer and the second display panel. The pixel overlap area further includes a reflection region. The transparent section includes a transmission region. A second reflection layer is further disposed in the pixel overlap area. The second reflection layer is arranged in the reflection region. A second light mixing cavity is formed between the second reflection layer and the first display panel. The first light mixing region is communicated to the second light mixing cavity through the transmission region.

In some embodiments, a diffusion plate is disposed in the pixel overlap area. The diffusion plate is arranged between the first reflection layer and the second display panel, and the thickness of the diffusion plate is S2, wherein S2<S1.

In some embodiments, a diffusion plate is disposed in the pixel overlap area. The diffusion plate includes a first diffusion plate and a second diffusion plate. The first diffusion plate is disposed in the transparent section. The second diffusion plate is disposed in the opaque section. A black matrix is disposed on the side of the second diffusion plate adjacent to the first display panel.

In some embodiments, the double-sided display device further includes a light intensity sensor and a light source compensation module. The light source compensation module includes a light source and a compensation circuit. The compensation circuit inputs an electrical signal to the light source to control the light-emitting brightness of the light source and whether it emits light. The light source is arranged on a side of the second display panel. The light emitted by the light source is guided into the pixel overlap area through a light guide structure. The light intensity sensor is connected to the compensation circuit. The light intensity sensor detects the brightness of the ambient light, and generates a corresponding compensation voltage according to the brightness of the ambient light and outputs it to the compensation circuit, so that the compensation circuit outputs a corresponding electrical signal to the light source to control the light-emitting brightness of the light source and whether it emits light.

In some embodiments, the first display panel is an OLED display panel. The pixel overlap area corresponding to each pixel of the OLED display panel includes a transparent section and an opaque section. The width of the transparent section is less than or equal to the width of the opaque section.

The present application further discloses a driving method of a double-sided display device, which is used to drive the double-sided display device. The double-sided display device includes a first display panel and a second display panel. The first display panel displays a front side image of the double-sided display device. The second display panel displays a back side image of the double-sided display device. A pixel overlap area is disposed between the first display panel and the second display panel. The pixel overlap area is divided into a plurality of opaque sections and a plurality of transparent sections.

The first display panel includes an organic light-emitting layer. The organic light-emitting layer emits light in a first direction and a second direction. The first direction and the second direction are opposite directions. The light in the first direction displays the front side image on a display surface of the first display panel. The light in the second direction passes through the transparent section of the pixel overlap area and displays the back side image on a display surface of the second display panel.

The driving method includes:
inputting a driving signal of the first display panel to make the organic light-emitting layer emit light in the first direction and the second direction;
obtaining a brightness of the organic light-emitting layer through the pixel overlap area as a backlight brightness of the second display panel; and
generating a driving signal for the second display panel according to the backlight brightness and signal source data of the second display panel;

The pixel overlap area includes a plurality of opaque sections and transparent sections. The first direction and the second direction are opposite directions. The light in the first direction displays an image on a display surface of the first display panel. The light in the second direction passes through the transparent section of the pixel overlap area and then is subjected to light mixing in the entire pixel overlap area.

In some embodiments, the double-sided display device includes a light intensity sensor, which is used to detect the brightness of ambient light. The operation of obtaining the brightness of the organic light-emitting layer through the pixel overlap area as the backlight brightness of the second display panel includes the following:
detecting a brightness of the ambient light, and obtaining an actual brightness of the pixel overlap area according to the brightness of the ambient light and the brightness of the organic light-emitting layer through the pixel overlap area as the backlight brightness of the second display panel.

In some embodiments, the double-sided display device includes a light source compensation module, and the light source compensation module includes a light source arranged on the side to compensate the brightness of the pixel overlap area. The operation of generating a driving signal of the second display panel according to the backlight brightness and the signal source data of the second display panel includes:
generating a light supplementation driving signal of a light source in the light source compensation module and an actual driving signal of the second display panel according to the source data of the second display panel and the brightness of the pixel overlap area.

Compared with the display devices realizing double-sided display by stacking LCD screens or OLED screens, the present application takes into account the problem that the stacked display panels have a relatively large thickness or high power consumption, so the double-sided display device is no longer formed by stacking LCD screens, but a second display panel including an LCD display screen and a first display panel including an OLED display screen are stacked as a double-sided display. The organic light-emitting layer of the OLED panel can emit light in a first direction and a second direction in opposite directions, and display is realized on the display surfaces of the two panels individually. In order to prevent the OLED light-emitting layer from affecting the display of the second display panel, a partially transparent pixel overlap area is disposed between the first display panel and the second display panel, so that the light emitted by the organic light-emitting layer is fully utilized. The light passing through the transparent section of the organic light-emitting layer is subjected to mixing to prevent the light-emitting area of the organic light-emitting layer from affecting the display area of the second display panel. It is beneficial to reduce the thickness and power consumption of the entire double-sided display device, and at the same time improve the double-sided display effect of the double-sided display device.

### BRIEF DESCRIPTION OF DRAWINGS

The accompanying drawings are used to provide a further understanding of the embodiments according to the present application, and constitute a part of the specification. They are used to illustrate the embodiments according to the present application, and explain the principles of the present application in conjunction with the text description. Apparently, the drawings in the following description merely represent some embodiments of the present disclosure, and for those having ordinary skill in the art, other drawings may also be obtained based on these drawings without investing creative. In the drawings:

FIG. 1 is a schematic diagram of a double-sided display device according to a first embodiment of the present application.

FIG. 2 is a schematic diagram of a double-sided display device according to a second embodiment of the present application.

FIG. 3 is a schematic diagram of a double-sided display device according to a third embodiment of the present application.

FIG. 4 is a schematic diagram of another double-sided display device according to the third embodiment of the present application.

FIG. 5 is a schematic diagram of a double-sided display device according to a fourth embodiment of the present application.

FIG. 6 is a schematic diagram of another double-sided display device according to the fourth embodiment of the present application.

FIG. 7 is a schematic diagram of a double-sided display device according to a fifth embodiment of the present application.

FIG. 8 is a flow chart of a driving method of the sixth embodiment according to the present application.

In the drawings: 100, double-sided display device; 110, first display panel; 111, organic light-emitting layer; 120, second display panel; 121, liquid crystal layer; 122, black matrix; 130, pixel overlap area; 131, first reflection layer; 132, second reflection layer; 133, first light mixing region; 134, second light mixing cavity; 140, transparent section; 141, transmission region; 142, reflection region; 150, opaque section; 160, diffusion plate; 161, first diffusion plate; 162, second diffusion plate; 170, light intensity sensor; 180, light source compensation module; 181, light source; 182, compensation circuit; 190, glass substrate.

### DETAILED DESCRIPTION OF EMBODIMENTS

It should be understood that the terms used herein, the specific structures and functional details disclosed therein are merely representative for describing some specific embodiments, but the present application can be implemented in many alternative forms and should not be construed as being limited to only these embodiments described herein.

The present application will be described in detail below with reference to the accompanying drawings and some optional embodiments.

### Embodiment 1

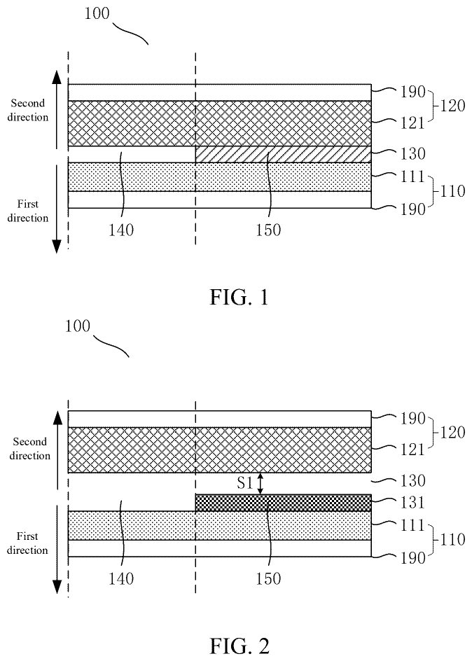

Referring to FIG. 1, as a first embodiment of the present application, a double-sided display device 100 is disclosed. The double-sided display device 100 includes a first display panel 110 and a second display panel 120. The first display panel 110 displays a front side image of the double-sided display device 100. The second display panel 120 displays a back side image of the double-sided display device 100. A pixel overlap area 130 is disposed between the first display panel 110 and the second display panel 120. The first display panel 110 is an OLED panel. The second display panel 120 is an LCD panel. The pixel overlap area 130 is divided into a plurality of opaque sections 150 and a plurality of transparent sections 140. The widths of the transparent section 140 and the opaque section 150 may be set differently. The width of the opaque section 150 may be set larger than the width of the transparent section 140 to prevent the light source 181 of the organic light-emitting layer 111 from affecting the display of the second display panel 120 due to excessive brightness. The OLED display panel of the present application is an OLED display panel with a COE (Color film on Encapsulation, namely forming a color filter on a thin film encapsulation structure) architecture. It should be noted that COE refers to the Color Filter process of depositing R/G/B color fiters on R/G/B pixels after the OLED completes the thin film encapsulation. In order to prevent cross-color between different colors of light, a black matrix 122 (BM) is disposed between different color filters to absorb colored light at the edges of the color filters and natural light in the non-pixel opening area of the environment. Depending on the type of organic light-emitting layer 111, it can be divided into white light OLED, blue light OLED, and true RGB OLED, etc.

In this embodiment, the first display panel 110 may include an organic light-emitting layer 111 that emits white light. A transparent glass substrate 190 is disposed on each of the side of the organic light-emitting layer 111 facing away from the liquid crystal layer 121 and the side of the liquid crystal layer 121 facing away from the organic light-emitting layer 111. The organic light-emitting layer 111 emits light in a first direction and a second direction. The first direction and the second direction are opposite directions. The light transmitting in the first direction displays the front side image on the display surface of the first display panel 110, i.e., the glass substrate 190. The light transmitting in the second direction passes through the transparent section 140 of the pixel overlap area 130 and displays the back side image on the display surface of the second display panel 120.

By utilizing the characteristics of the organic light-emitting layer 111 of the OLED emitting light from both sides, one side allows the OLED panel to display an image normally, and the light emitted from the other side is used as the backlight light source 181 of the LCD panel. Because the brightness of the organic light-emitting layer 111 has a relatively great influence on the display of the second display panel 120, if the light emitted by the organic light-emitting layer 111 is simply used as the backlight of the second display panel 120, the backlight of the second display panel 120 may be too bright, and the user can see the organic light-emitting layer 111 of the first display panel 110 through the second display panel 120, thereby affecting the user's viewing experience. Therefore, a pixel overlap area 130 is disposed between the two panels to absorb and disperse the light in the second direction of the organic light-emitting layer 111, so that the backlight is more uniform, thereby preventing the brightness of the organic light-emitting layer 111 from affecting the normal display due to excessive brightness. Furthermore, part of the pixel overlap area 130 is opaque, which can also avoid the problem that after light enters the pixel overlap area 130, the pixel overlap area 130 serves as the backlight of the OLED so that the light returns to the organic light-emitting layer 111, thereby affecting the image display of the OLED and causing the non-luminous pixels of the OLED to be bright.

### Embodiment 2

As shown in FIG. 2, as a second embodiment of the present application, it is a further refinement of the first embodiment described above. A first reflection layer 131 is disposed in the pixel overlap area 130, and the first reflection layer 131 is arranged in the opaque section 150. The first reflection layer 131 is spaced apart from the second display panel 120. Along the first direction, the spacing between the first reflection layer 131 and the second display panel 120 is S1, wherein 0<S1≤3 mm. The first reflection layer 131 in the pixel overlap area 130 reflects the ambient light passing through the liquid crystal of the second display panel 120, so that the light emitted by the organic light-emitting layer 111 and passing through the transparent section 140 is mixed with the ambient light. That is, the light emitted by the organic light-emitting layer 111 and the ambient light are superimposed to increase the brightness of the pixel overlap area 130 as the backlight, thereby avoiding the situation where the brightness of the organic light-emitting layer 111 of the OLED is relatively low and the LCD needs to display a relatively high brightness but the brightness is insufficient. The first reflection layer 131 is opaque and may be single-sided reflective, realizing reflection near the second display panel 120. It may also be double-sided reflective, meaning reflecting on both sides of the reflective layer, thus reflecting back the light emitted by the organic light-emitting layer 111 under the opaque section 150, thereby improving the display brightness of the organic light-emitting layer 111 on the OLED panel.

### Embodiment 3

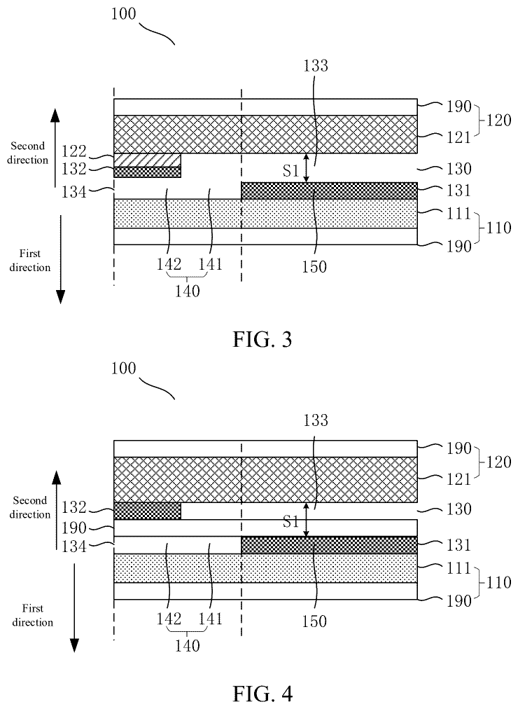

As shown in FIG. 3, as a third embodiment of the present application, it is a further refinement of the second embodiment described above. The pixel overlap area 130 further includes a reflection region 142. The transparent section 140 further includes a transmission region 141. A second reflection layer 132 is disposed in the pixel overlap area 130, and the second reflection layer 132 is arranged in the reflection region 142. A first light mixing region 133 is formed between the first reflection layer 131 and the second display panel 120. A second light mixing cavity 134 is formed between the second reflection layer 132 and the first display panel 110. The first light mixing region 133 is communicated to the second light mixing cavity 134 through the transmission region 141. The second reflection layer 132 is disposed corresponding to the transparent section 140, so that the width of the transparent section 140 is further reduced. A black matrix 122 may be disposed on the second display panel 120 corresponding to the second reflection layer 132. The black matrix 122 may be disposed on a side of the second reflection layer 132 adjacent to the second display panel 120, or may be disposed on other film layers of the second display panel 120. In the first direction, a projection area of the black matrix 122 is greater than or equal to an area of the second reflection layer 132. The second reflection layer 132 may allow the light emitted in the second direction by the organic light-emitting layer 111 of the OLED to be emitted back to the OLED panel, further efficiently utilizing the light emitted by the organic light-emitting layer. In order to prevent the light in the diffusion plate 160 from returning to the OLED panel again, in addition to reducing the width of the transmission region 141, the transmission region 141 may also be set to a convex shape, so that light can enter easily but exits difficultly, thereby preventing the pixel overlap area 130 as the backlight of the OLED from providing brightness to OLED pixels that do not need to be displayed thus causing display abnormality. In order to better stack the two panels, a glass substrate 190 may be disposed between the two panels, as shown in FIG. 4.

### Embodiment 4

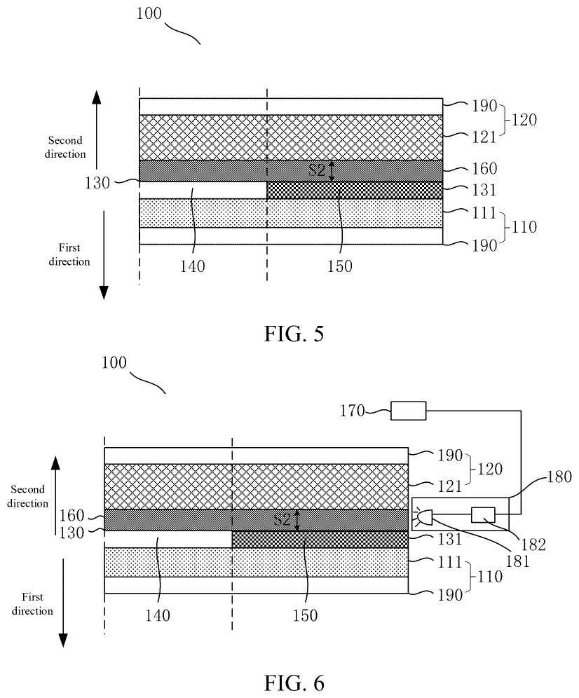

As shown in FIG. 5, as a fourth embodiment of the present application, it is a further refinement and improvement of the first embodiment. Different from the above embodiment, a diffusion plate 160 is disposed in the pixel overlap area 130. The diffusion plate 160 is disposed between the first reflection layer 131 and the second display panel 120. The thickness of the diffusion plate 160 is S2, where S2<S1. This embodiment mainly absorbs and diffuses the light transmitting in the second direction of the organic light-emitting layer 111, so that the pixel overlap area 130 can emit light uniformly, better providing backlight for the second display panel 120, thus avoiding uneven backlight brightness resulting in uneven display. Compared to the above third embodiment, the second reflection layer 132 is not provided, and the diffusion is mainly performed by reflecting ambient light and absorbing the light of the organic light-emitting layer 111 that passes through the transparent section 140, so that the backlight of the second display panel 120 is uniform while ensuring the brightness. However, the second reflection layer 132 may also be provided, and the two do not conflict. Furthermore, because a light mixing cavity can be formed between the first reflection layer 131 and the second reflection layer 132, a certain distance between the two needs to be reserved. However, if a diffusion plate 160 is provided, no other gap needs to be reserved after adding the diffusion plate 160 between the first reflection layer 131 and the second display panel 120, thereby reducing the thickness of the entire double-sided display device 100.

Further, as shown in FIG. 6, considering that sometimes the pixels corresponding to the OLED panel are not bright or have low brightness, while the corresponding LCD panel needs to have a higher brightness, meaning the backlight brightness may be insufficient, so it is also necessary to modify and compensate the backlight brightness of the LCD panel. Accordingly, the double-sided display device 100 further includes a light intensity sensor 170 and a light source compensation module 180. The light source compensation module 180 includes a light source 181 and a compensation circuit 182. The compensation circuit 182 inputs an electrical signal to the light source 181 to control the light-emitting brightness of the light source 181 and whether it emits light.

The light source 181 is arranged on a side of the second display panel 120. The light emitted by the light source 181 is guided into the pixel overlap area 130 through a light guide structure. The light intensity sensor 170 is connected to the compensation circuit 182. The light intensity sensor 170 detects the brightness of the ambient light, and generates a corresponding compensation voltage based on the brightness of the ambient light and outputs the compensation voltage to the compensation circuit 182, so that the compensation circuit 182 outputs a corresponding electrical signal to the light source 181 to control the brightness of the light source 181 and whether it emits light. During the day, because the light is relatively bright, it may be not necessary to turn on the compensation mode, and the corresponding compensation module can be manually controlled not to operate. At night, the compensation module may be turned on, and a corresponding signal is generated according to the detection result to control the light source compensation module 180 to compensate the brightness of the pixel overlap area 130. Of course, it is not limited to differing between night and day, and the compensation mode can be turned on in both cases. The light intensity sensor 170 detects the external brightness in real time to compensate the brightness of the pixel overlap area 130, thereby ensuring the display effect of the second display panel 120.

### Embodiment 5

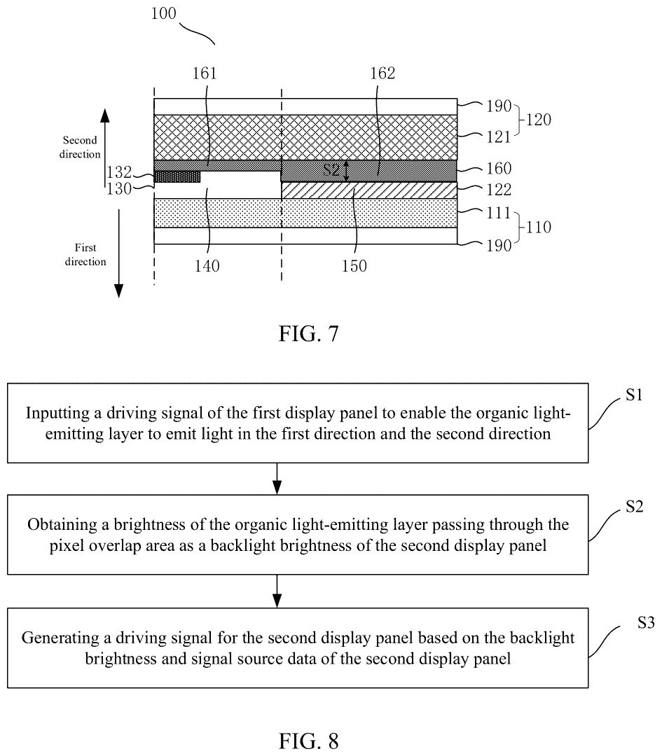

As shown in FIG. 7, as a fifth embodiment of the present application, the pixel overlap area 130 includes a diffusion plate 160. Different from the previous embodiment, the diffusion plate 160 includes a first diffusion plate 161 and a second diffusion plate 162. The thicknesses of the two diffusion plates 160 may be different. The first diffusion plate 161 is arranged in the transparent section 140. The second diffusion plate 162 is arranged in the opaque section 150. A black matrix 122 is arranged on the side of the second diffusion plate 162 adjacent to the first display panel 110. The black matrix 122 is arranged in the opaque section 150 of the pixel overlap area 130 so that this part of the pixel overlap area 130 is opaque. When one of two adjacent pixels in the OLED panel is lit and the other is not, if the two corresponding pixels of the LCD are both lit, then the diffusion plate 160 needs to serve as the backlight of the two pixels of the LCD panel and provide the light source 181 for the two pixels of the LCD panel. In this case, however, the corresponding OLED pixel that is not lit will also be affected by the brightness of the diffusion plate 160 to realize display, causing display disorder, so that the black matrix 122 is disposed to block the light of the diffusion plate 160 from returning to the OLED panel. A second reflection layer 132 may also be disposed on the corresponding first diffusion plate 161 to reflect the light from the organic light-emitting layer 111 back.

The pixel overlap area 130 corresponding to each pixel of the OLED display panel may include a transparent section 140 and an opaque section 150. In this area, there is light emitted from the organic light-emitting layer of the OLED display panel, and there is also light from the external ambient light entering through the LCD panel. Multiple types of light produce mixed light in the pixel overlap area, which can make the light finally emitted from the LCD panel uniform. The width of the transparent section 140 is less than or equal to the width of the opaque section 150. The reason for reducing the width of the transparent section 140 is mainly to avoid the pixel overlap area 130 from being reused as the backlight of the first display panel 110 while being used as the backlight of the second display panel 120, affecting the display of the first display panel 110. Therefore, not only the amount of light passing through the transparent section 140 should be considered to ensure that the pixel overlap area 130 can be used as the backlight of the second display panel 120 without insufficient brightness, but also the pixel overlap area 130 should be reduced as the backlight of the first display panel 110 as much as possible, which may otherwise cause some pixels of the first display panel 110 to display abnormally. Therefore, the width of the transparent section 140 is set to be smaller than the width of the opaque section 150. Unlike a possible transparent section 140, the light in the second direction can easily enter from the transparent section 140 in this application, but it is more difficult for the light to emerge from the first direction after entering. The shape of the transparent section 140 may be set to be convex, or a light path channel changing from a small size to large size can be disposed on the side of the pixel overlap area 130 adjacent to the organic light-emitting layer 111, so that the light can easily enter, while when it exits, it can be reflected by various microstructures and emitted along the second direction.

### Embodiment 6

Referring to FIG. 8, as a sixth embodiment of the present application, a driving method of a double-sided display device is disclosed, which is used to drive the double-sided display device as described in any of the above embodiments, and the driving method comprises the following operations:

S1: inputting a driving signal of the first display panel to make the organic light-emitting layer emit light in the first direction and the second direction;

S2: obtaining a brightness of the organic light-emitting layer through the pixel overlap area as a backlight brightness of the second display panel; and

S3: generating a driving signal for the second display panel 120 according to the backlight brightness and signal source data of the second display panel 120;

Referring to FIGS. 1 to 7, the pixel overlap area 130 includes a plurality of opaque sections 150 and transparent sections 140. The first direction and the second direction are opposite directions. The light in the first direction displays an image on a display surface of the first display panel 110. The light in the second direction passes through the transparent section 140 of the pixel overlap area 130 and then is subjected to light mixing in the entire pixel overlap area 130.

The organic light-emitting layer 111 emits light in two opposite directions. The light in the first direction displays a front side image on the display surface of the first display panel 110. The light in the second direction enters the pixel overlap area 130 is subjected to light mixing being emitted. Therefore, the pixel overlap area 130 is equivalent to a backlight. The brightness of the pixel overlap area 130 is the backlight brightness of the second display panel 120. The second display panel 120 generates a driving signal for the second display panel 120 according to the brightness of the backlight and the signal source data, and controls the corresponding liquid crystal rotational angle so that the display surface of the second display panel 120 displays the back side image normally. Furthermore, because part of the pixel overlap area 130 is not transparent, the pixel overlap area 130 can reduce the light entering the first display panel 110, avoiding abnormal light emission when some pixels of the first display panel 110 do not need to emit light.

The double-sided display device 100 may include a light intensity sensor 170, which is used to detect the brightness of ambient light. The operation S2 includes the following:

S21: detecting a brightness of the ambient light, and obtaining an actual brightness of the pixel overlap area according to the brightness of the ambient light and the brightness of the organic light-emitting layer through the pixel overlap area as the backlight brightness of the second display panel.

Considering the influence of ambient light, the brightness of the pixel overlap area 130 is not only affected by the light emitted from the organic light emitting layer 111 from the second direction, but also by the external ambient light passing through the liquid crystal layer 121 and entering the pixel overlap area 130. Therefore, when the pixel overlap area 130 is used as a backlight, the light emitted by the organic light emitting layer 111 and the ambient light passing through the liquid crystal layer 121 should be considered at the same time, and the actual backlight brightness of the pixel overlap area 130 when used as a backlight is determined according to the brightness of the two, so as to generate a corresponding driving signal to drive the second display panel 120. In addition, a sensor can be added at the position of the pixel overlap area 130 to directly obtain the actual backlight brightness of the pixel overlap area 130.

In addition, the double-sided display device 100 includes a light source compensation module 180, and the light source compensation module 180 includes a light source 181 arranged on the side to compensate the brightness of the pixel overlap area 130. The operation S3 includes:

S31: generating a light supplementation driving signal of a light source in the light source compensation module 180 and an actual driving signal of the second display panel according to the source data of the second display panel and the brightness of the pixel overlap area.

The light intensity sensor 170 detects the external brightness in real time to compensate the brightness of the pixel overlap area 130, thereby ensuring the display effect of the second display panel 120. Specifically, the LCD pixel and the OLED pixel are independently controlled by the respective thin film transistors and are independently designed. That is, the resolution and refresh rate are independent for each of the display panels. When the ambient light is relatively weak and the screen brightness of the LCD pixel is too dark, the compensation mode can be turned on, so that the side light source 181 emits light which is introduced into the pixel overlap area 130 as compensation light. In addition, the OLED pixel display surface can also be adjusted to a high refresh mode, while the electronic paper pixel display surface adopts a low refresh mode, that is, the OLED display brightness of several frames is used for the display brightness of one frame of the electronic paper display. That is, the compensation value is associated with the refresh rate. Different compensation values correspond to different refresh rates. The larger the compensation value, the larger the corresponding refresh rate, but it cannot exceed the rated refresh rate of the OLED pixel (that is, the maximum refresh rate set independently) to avoid affecting the display of the OLED display surface. This embodiment can further increase the brightness compensation value of the OLED pixel to the LCD pixel by adjusting the refresh rate on the basis of turning on the OLED pixel to compensate the electronic paper pixel.

It should be noted that the limitations of the various steps involved in this solution are not to be interpreted to limit the order of the steps, under the premise of not affecting the implementation of the specific solution. For example, detecting the state of the display device and detecting the display mode of the display device can be detected at the same time, or the state of the display device can be detected first before detecting the display mode of the display device, or the display mode of the display device can be detected first before detecting the state of the display device. That is, the steps written earlier can be executed first, or later, or even at the same time with the steps written later. As long as this solution can be implemented, it should be regarded as falling in the scope of protection of this application.

It should be noted that the inventive concept of the present application can be formed into many embodiments, but the length of the application document is limited and so these embodiments cannot be enumerated one by one. Therefore, should no conflict be present, the various embodiments or technical features described above can be arbitrarily combined to form new embodiments. After the various embodiments or technical features are combined, the original technical effects may be enhanced.

The foregoing is a further detailed description of the present application with reference to some specific optional implementations, but it cannot be determined that the specific implementation of the present application is limited to these implementations. For those having ordinary skill in the technical field to which the present application pertains, several deductions or substitutions may be made without departing from the concept of the present application, and all these deductions or substitutions should be regarded as falling in the scope of protection of the present application.

What is claimed is:

1. A double-sided display device, comprising:
a first display panel, configured to display a front side image of the double-sided display device; and
a second display panel, configured to display a back side image of the double-sided display device; wherein there is disposed a pixel overlap area between the first display panel and the second display panel, wherein the pixel overlap area is divided into a plurality of opaque sections and a plurality of transparent sections;
wherein the first display panel comprises an organic light-emitting layer operate to emit light in a first direction and a second direction, the first direction and the second direction being opposite directions; wherein light in the first direction is operative to display the front side image on a display surface of the first display panel, wherein light in the second direction is operative to pass through each of the plurality of transparent sections of the pixel overlap area to display the back side image on a display surface of the second display panel

2. The double-sided display device as recited in claim 1, wherein there is disposed a first reflection layer in the pixel overlap area, wherein the first reflection layer is arranged in the opaque section, wherein the first reflection layer and the second display panel are spaced apart from each other along the first direction, wherein a spacing between the first reflection layer and the second display panel is S1, where 0<S1≤3 mm.

3. The double-sided display device as recited in claim 2, wherein there is defined a first light mixing region between the first reflection layer and the second display panel, wherein the pixel overlap area further comprises a reflection region, wherein each of the plurality of transparent sections comprises a transmission region; wherein there is further disposed a second reflection layer in the pixel overlap area, wherein the second reflection layer is arranged in the reflection region; wherein there is defined a second light mixing cavity between the second reflection layer and the first display panel; wherein the first light mixing region is optically connected with the second light mixing cavity through the transmission region.

4. The double-sided display device as recited in claim 2, wherein there is disposed a diffusion plate in the pixel overlap area, wherein the diffusion plate is arranged between the first reflection layer and the second display panel, wherein the diffusion plate has a thickness of S2, where S2<S1.

5. The double-sided display device as claimed in claim 1, wherein there is disposed a diffusion plate in the pixel overlap area, wherein the diffusion plate comprises a first diffusion plate and a second diffusion plate, wherein the first diffusion plate is disposed in each of the plurality of transparent sections, wherein the second diffusion plate is disposed in each of the plurality of opaque sections, wherein there is disposed a black matrix on a side of the second diffusion plate facing towards the first display panel.

6. The double-sided display device as recited in claim 4, further comprising a light intensity sensor and a light source compensation module, wherein the light source compensation module comprises a light source and a compensation circuit, wherein the compensation circuit is configured to input an electrical signal to the light source to control a light-emitting brightness of the light source and whether the light source emits light; wherein the light source is arranged on a side of the second display panel, wherein light emitted by the light source is introduced into the pixel overlap area through a light guide structure; wherein the light intensity sensor is connected to the compensation circuit, wherein the light intensity sensor is configured to detect a brightness of ambient light, and generate a corresponding compensation voltage based on the brightness of the ambient light and output the compensation voltage to the compensation circuit, and wherein the compensation circuit is configured to output a corresponding electrical signal to the light source to control the light-emitting brightness of the light source and whether the light source emits light.

7. The double-sided display device as recited in claim 1, wherein the first display panel is an OLED display panel, wherein the pixel overlap area comprises one transparent section and one opaque section responding to each pixel of the OLED display pane; wherein a width of the transparent section is less than or equal to a width of the opaque section.

8. The double-sided display device as recited in claim 1, wherein the first display panel comprises a color film layer, wherein the color film layer comprises a color filter layer and a black matrix, wherein the color filter layer comprises a plurality of color filters of different colors, wherein the black matrix is arranged between the color filters of different colors.

9. The double-sided display device as recited in claim 2, wherein the first reflection layer is double-sided reflective, and wherein along the first direction, the side of the first reflective layer facing towards the organic light-emitting layer and the side of the first reflective layer facing away from the organic light-emitting layer are both reflective.

10. The double-sided display device as recited in claim 3, wherein there is disposed a glass substrate between the first display panel and the second display panel, wherein one side of the glass substrate abuts against the first reflection layer, and wherein another side of the glass substrate abuts against the second reflection layer.

11. The double-sided display device as recited in claim 3, wherein there is disposed a diffusion plate in the pixel overlap area, wherein the diffusion plate is arranged between the first reflection layer and the second reflection layer, and wherein the diffusion plate has a thickness of S2, wherein S2<S1.

12. The double-sided display device as recited in claim 5, wherein the first diffusion plate has a thickness that is less than a thickness of the second diffusion plate.

13. The double-sided display device as claimed in claim 3, wherein there is disposed a diffusion plate in the pixel overlap area, wherein the diffusion plate comprises a first diffusion plate and a second diffusion plate, wherein the first diffusion plate is disposed in each of the plurality of transparent sections, the second diffusion plate is disposed in each of the plurality of opaque sections, wherein there is disposed a black matrix on a side of the second diffusion plate facing towards the first display panel, wherein the second reflection layer is disposed on a side of the first diffusion plate facing towards the first display panel.

14. The double-sided display device as recited in claim 1, wherein the organic light-emitting layer comprises a white light organic light-emitting layer, a blue light organic light-emitting layer, and an RGB organic light-emitting layer.

15. The double-sided display device as recited in claim 3, wherein each of the plurality of transmission regions has a convex shape to gather the light reflected by the organic light-emitting layer along the second direction and emit the light into the second light mixing cavity.

16. A driving method of a double-sided display device wherein the double-sided display device comprises a first display panel and a second display panel, wherein the first display panel is configured to display a front side image of the double-sided display device, the second display panel is configured to display a back side image of the double-sided display device, wherein there is disposed a pixel overlap area between the first display panel and the second display panel, wherein the pixel overlap area is divided into a plurality of opaque sections and a plurality of transparent sections; wherein the first display panel comprises an organic light-emitting layer operative to emit light in a first direction and a second direction, the first direction and the second direction being opposite directions; wherein the light in the first direction is operative to display the front side image on a display surface of the first display panel, wherein the light in the second direction is operative to pass through each of the plurality of transparent sections of the pixel overlap area and is operative to display the back side image on a display surface of the second display panel, wherein the driving method comprises:
inputting a driving signal of the first display panel to enable the organic light-emitting layer to emit light in the first direction and the second direction;
obtaining a brightness of the organic light-emitting layer passing through the pixel overlap area as a backlight brightness of the second display panel; and
generating a driving signal for the second display panel based on the backlight brightness and signal source data of the second display panel;
wherein the pixel overlap area comprises a plurality of opaque sections and plurality of transparent sections; wherein the first direction and the second direction are opposite directions, wherein the light of the first direction is operative to display an image on the display surface of the first display panel, wherein the light of the second direction is operative to pass through each of the plurality of transparent sections of the pixel overlap area and then is subjected to light mixing in the entire pixel overlap area.

17. The driving method as recited in claim 16, wherein the double-sided display device comprises a light intensity sensor used to detect a brightness of ambient light, wherein the operation of obtaining the brightness of the organic light-emitting layer passing through the pixel overlap area as the backlight brightness of the second display panel includes:
detecting the brightness of the ambient light, and obtaining an actual brightness of the pixel overlap area based on the brightness of the ambient light and the brightness of the organic light-emitting layer passing through the pixel overlap area as the backlight brightness of the second display panel.

18. The driving method as recited in claim 16, wherein the double-sided display device comprises a light source compensation module, wherein the light source compensation module comprises a light source disposed on a side to compensate the brightness of the pixel overlap area, wherein the operation of generating a driving signal for the second display panel based on the backlight brightness and the signal source data of the second display panel comprises:
generating a light supplementation driving signal for the light source in the light source compensation module and an actual driving signal of the second display panel, based on the signal source data of the second display panel and the brightness of the pixel overlap area.

19. The driving method as recited in claim 16, wherein the double-sided display device comprises a light intensity sensor used to detect a brightness of ambient light, wherein the operation of obtaining the brightness of the organic light-emitting layer passing through the pixel overlap area as the backlight brightness of the second display panel comprises:
detecting the brightness of the ambient light, adjusting a refresh rate of the first display panel, and obtaining an actual brightness of the pixel overlap area based on the brightness of the ambient light and the brightness of the organic light-emitting layer passing through the pixel overlap area as the backlight brightness of the second display panel.

20. The driving method as recited in claim 18, wherein the second display panel is a liquid crystal display panel, wherein there is disposed a first reflection layer disposed in the pixel overlap area, wherein the first reflection layer is arranged in each of the plurality of opaque sections; wherein the first reflection layer and the second display panel are spaced apart from each other; wherein there is defined a first light mixing region between the first reflection layer and the second display panel; wherein the pixel overlap area further comprises a reflection region, wherein each of the plurality of transparent sections comprises a transmission region; wherein there is further disposed a second reflection layer in the pixel overlap area, wherein the second reflection layer is arranged in the reflection region, wherein there is defined a second light mixing cavity between the second reflection layer and the first display panel, wherein the first light mixing region is optically connected with the second light mixing cavity through the transmission region; wherein the transmission region is disposed between the first reflection layer and the second reflection layer.
